(19) United States
(12) Patent Application Publication
(10) Pub. No.: US 2011/0291685 A1
(43) Pub. Date: Dec. 1, 2011

(54) PROBE

(75) Inventor: Chikaomi Mori, Hyogo (JP)

(73) Assignee: Japan Electronic Materials Corp.

(21) Appl. No.: 13/142,566

(22) PCT Filed: Mar. 19, 2009
(86) PCT No.: PCT/JP2009/055484

§ 371 Date: Aug. 3, 2011

(30) Foreign Application Priority Data
Dec. 29, 2008 (JP) 2008335761

(51) Int. Cl. G01R 1/067; G01R 31/00

(52) U.S. Cl. 324/755.01; 324/756.03

(57) ABSTRACT

[Problem]

It is aimed to provide a probe whose handling is easy at probe replacement and mounting times and which allows arrangement at a narrow pitch.

[Solving Means]

A probe is composed of a mounting portion mounted on an electrode of a probe card, an arm portion extending from the mounting portion, and a leading end portion provided at a leading end of the arm portion and contacting with an electrode of an object to be tested, where a handling plate held by a probe hand mechanism holding a probe is provided.

### REFERENCE TO EARLIER APPLICATION

This Application incorporates by reference and is a National Phase of PCT/JP2009/055484, filed Mar. 19, 2009, which claims priority to JP 2008-335761, filed Dec. 29, 2008.

The present invention relates to a probe provided with a handling plate.

### BACKGROUND ART

As probe cards used for testing a semiconductor, probe cards where needles are arranged at a pitch of about 70 μm to 80 μm are used according to progress of a probe to miniaturization due to high integration of a semiconductor wafer.

When such a probe card is repeatedly used, necessity for replacement of a probe occurs due to damage of the probe or the like. In order to perform probe replacement, a work for removing a probe to be replaced and mounting a new probe occurs.

### SUMMARY OF INVENTION

### [Technical Problem]

As described above, when a probe is re-mounted for probe replacement, if arrangement of probes is set at a narrow pitch, there is such a problem that it is difficult to grasp and position a probe mechanically, and it is difficult to apply heat for melting electrically-conductive joining agent such as solder, supplied to a probe mounting portion without imparting influence of the heat to an adjacent probe. Further, there is a problem about mechanical handling of a probe itself due to progress of miniaturization of a probe in recent years.

Further, in order to arrange probes at a narrower pitch, there is a problem that it is difficult to join a probe without imparting influence of heat to another probe adjacent thereto in a conventional joining method.

The present invention aims to provide a probe whose handling is easy at probe replacement and amounting times and which allows arrangement at a narrow pitch.

### [Solution to Problem]

A probe of the present invention is a probe which is composed of a mounting portion mounted on an electrode of a probe card, an arm portion extending from the mounting portion, and a leading end portion which is provided at a leading end of the arm portion and which contacts with an electrode of an object to be tested, characterized in that: including a handling plate provided on the probe and removed from the probe after mounting.

It is possible to provide a copper line extending from the handling plate to the mounting portion and serving as a heat passage.

Further, a suction face which is sucked by a probe hand mechanism is provided on the handling plate.

Then, it is possible to provide a recessed portion serving as a cutting edge at a root of the handling plate.

### [Advantageous Effects of Invention]

Since the probe of the present invention is composed of the mounting portion, the arm portion, and the leading end portion, and it is provided with the handling plate which is provided on the probe and is removed from the probe after mounting, it becomes possible to improve operability at a probe mounting time.

By providing a copper line extending from the handling plate to the mounting portion and serving as a heat passage, a heat conductivity from the handling plate to the mounting portion is improved so that it becomes possible to transfer heat to the electrically-conductive joining agent efficiently, which can result in enhancement of joining strength of the probe.

Further, by providing the suction face which is sucked by the probe hand mechanism on the handling mechanism, it becomes possible to suck the probe securely.

Then, by providing the recessed portion serving as a cutting edge at the root of the handling plate, it becomes possible to remove the handling plate easily.

### BRIEF DESCRIPTION OF DRAWINGS

FIG. 1 is a side diagram of a probe of a first embodiment,

FIG. 2 is a front diagram of the probe of the first embodiment,

FIG. 3 is a side diagram of a probe hand mechanism,

FIG. 4 are diagrams showing a state that a probe for replacement has been held by the probe hand mechanism, where FIG. 4(a) is a side diagram and FIG. 4(b) is a front diagram,

FIG. 5 is a sectional diagram of a probe card,

FIG. 6 is a plan diagram of arrangement of probes of the first embodiment,

FIG. 7 is a diagram showing a state that positioning of a probe is performed by the probe hand mechanism,

FIG. 8 is a diagram showing a state that the probe has been pressed on an electrode by the probe hand mechanism,

FIG. 9 is a diagram showing a state that a mounting portion of the probe is being cooled by air blow,

FIG. 10 is a diagram showing a state that holding of the probe performed by the probe hand mechanism has been released,

FIG. 11 is a diagram showing a state that a handling plate has been removed from the probe,

FIG. 12 is a front diagram of a state that the probe of the first embodiment has been joined to an electrode,

FIG. 13 are side diagrams of probes of a second embodiment, where two kinds of probes are provided with protruded portions at different positions,

FIG. 14 is a plan diagram of arrangement of probes of the second embodiment,

FIG. 15 is a side diagram when a beam has been provided between the protruded portions of the probe of the second embodiment,

FIG. 16 is a side diagram of a probe of a third embodiment,

FIG. 17 is an enlarged sectional diagram of a probe card mounted with the probe of the third embodiment,

FIG. 18 is a side diagram when a beam has been provided between the protruded portions of the probe of the third embodiment,

FIG. 19 is a side diagram of a probe of a fourth embodiment,

FIG. 20 is a side diagram of an intermediate layer of the probe of the fourth embodiment,

FIG. 21 is an enlarged sectional diagram of a probe card mounted with the probe of the fourth embodiment,

FIG. 22 is a side diagram when an opening has been provided in an intermediate layer of the probe of the fourth embodiment,

FIG. 23 is a side diagram of an intermediate layer of a probe of a fifth embodiment,

FIG. 24 is a side diagram of a probe of a sixth embodiment,

FIG. 25 is a sectional diagram of the probe taken along line A-A in FIG. 24,

FIG. 26 is an enlarged sectional diagram of a probe card mounted with the probe of the sixth embodiment,

FIG. 27 is a diagram showing a state that positioning of an unmounted probe is performed by the probe hand mechanism when a mounted probe is removed,

FIG. 28 is a diagram showing a state that an unmounted probe has been pressed on an arm portion of a mounted probe by the probe hand mechanism when the mounted probe is removed, and

FIG. 29 is a diagram showing a state that the mounted probe has been removed.

### EMBODIMENTS OF INVENTION

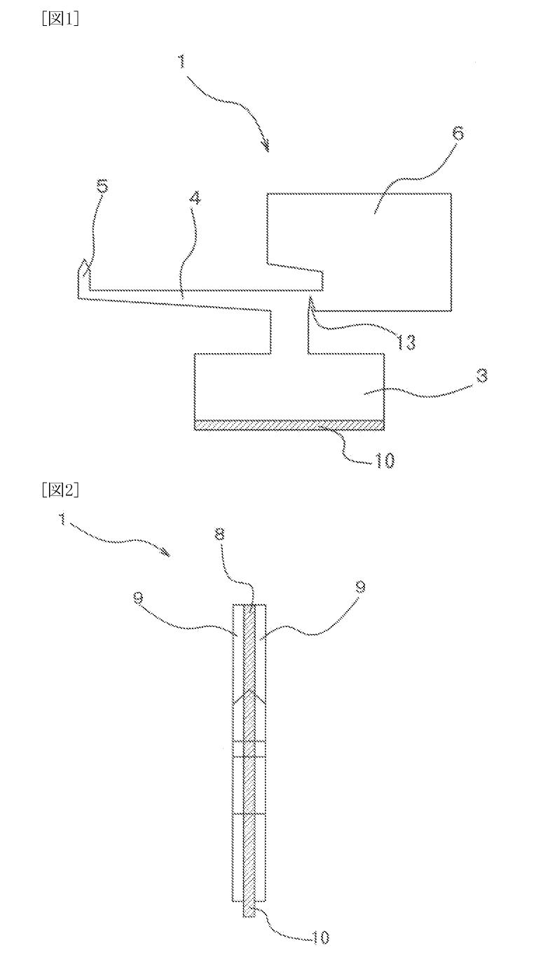

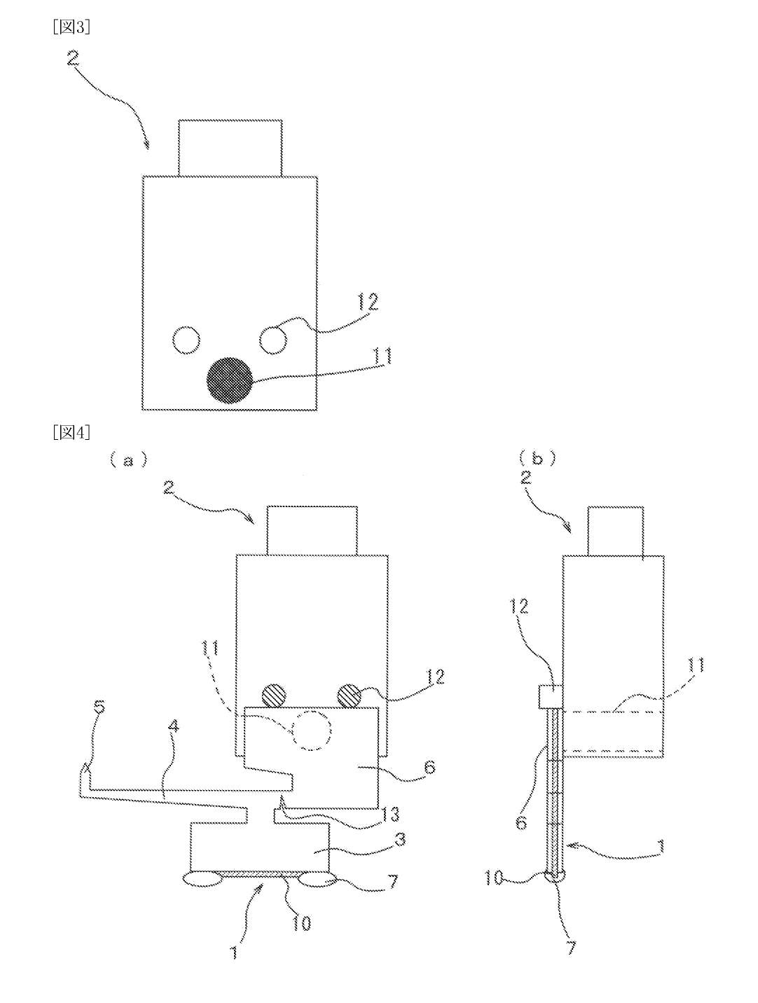

The present invention is described in detail with reference to the drawings. FIG. 1 is a side diagram of a probe 1 of a first embodiment of the present invention, and FIG. 2 is a front diagram of the probe 1 of the first embodiment.

As shown in FIG. 1, the probe 1 of the first embodiment of the present invention is composed of a mounting portion 3 joined to an electrode 17 of a probe card 14, an arm portion 4 extending from the mounting portion 3 and having a spring property, a leading end portion 5 provided at a leading end of the arm portion 4 and contacting with an electrode 35 of an object to be tested, and a handling plate 6 extending from the arm portion 4.

The probe 1 of the present invention is held by a probe hand mechanism 2 such as shown in FIG. 3, and it is heated after positioned at a predetermined position for mounting. The above handling plate 6 is provided in order to improve operability of such a work, and the handling plate 6 is sucked by a hole for probe suction 11 provided in the probe hand mechanism 2 and it is held by the probe hand mechanism 2.

By sucking the handling plate 6 by the probe hand mechanism 2 in this manner, the probe 1 is held, so that the handling plate 6 must have a certain size in order to emphasize operability at that time, which results in a size protruded beyond the leading end portion 5 of the probe 1 Therefore, after the probe 1 has been mounted, it is necessary to remove the handling plate 6.

A recessed portion 13 serving as a cutting edge is provided at a root of the handling plate 6 such that the handling plate 6 can be removed easily. By providing the recessed portion 13, it becomes possible to secure operability when the probe 1 is held and to easily remove the handling plate 6 which hinders at a testing time of a semiconductor device.

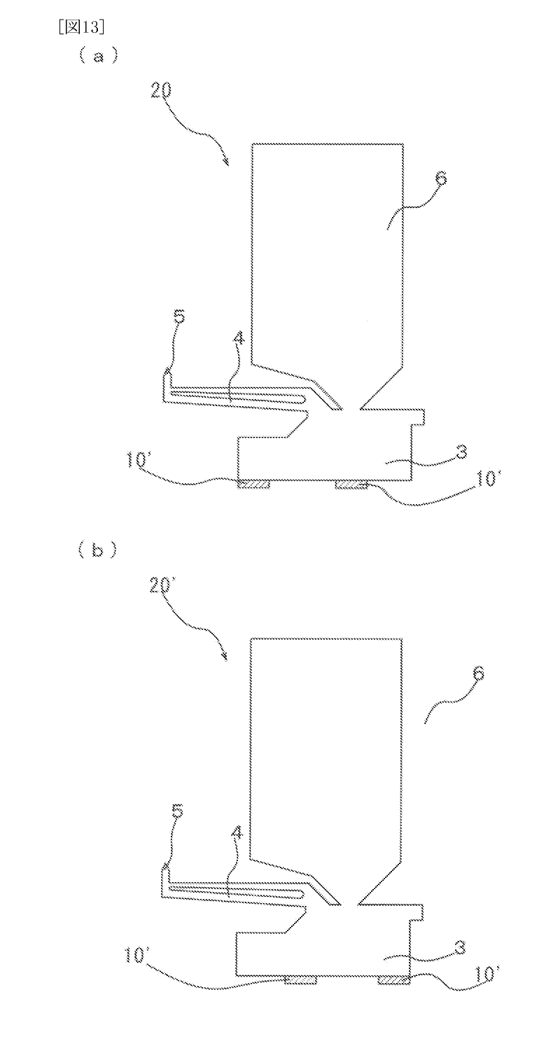

As shown by the front diagram in FIG. 2, the probe 1 has a three-layered structure where an intermediate layer 8 is sandwiched between outer layers 9. The intermediate layer 8 and the outer layers 9 are each formed in a shape of the above-described mounting portion 3, arm portion 4, leading end portion 5, and handling plate 6, but a lower end (a portion contacting with the electrode 17 when the probe 1 is mounted on the probe card 14) of the mounting portion 3 of the intermediate layer 8 is protruded beyond the outer layers 9, and when the probe 1 is joined, the mounting portions 3 of the outer layers 9 do not contact with the electrode 17 and a protruded portion 10 which is a projecting portion of the mounting portion 3 of the intermediate layer 8 is put in a contact state with the electrode 17 of the probe card 14, as shown in FIG. 12.

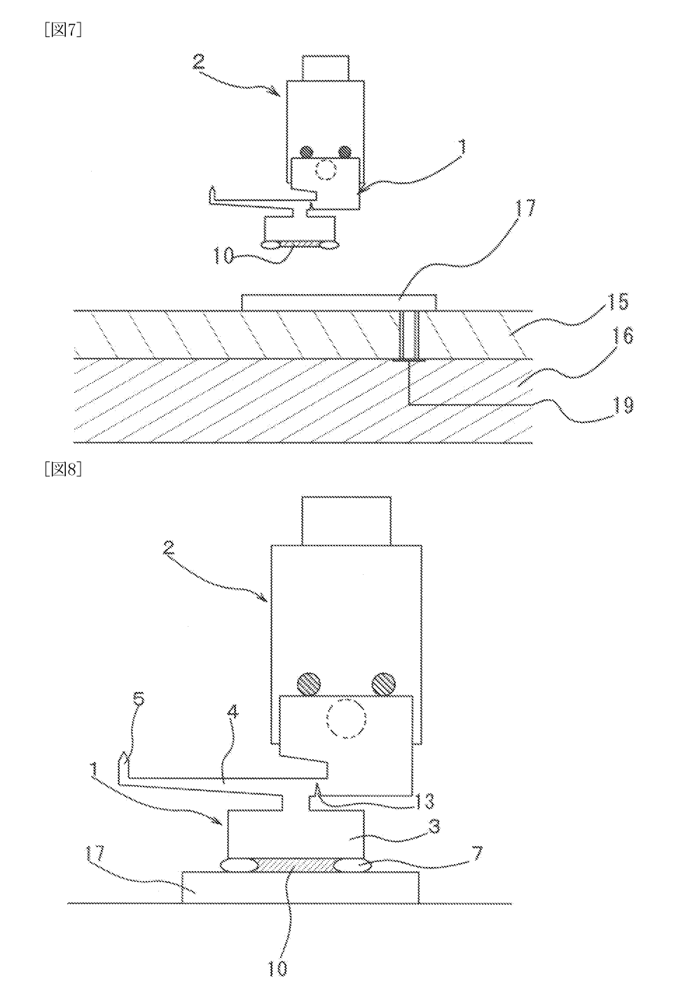

Next, the probe card 14 mounted with the probe 1 is described. As shown in FIG. 5, the probe card 14 includes a main substrate 16 having external terminals 18 which contact with pogo pins 34 of a tester 33 to be connected thereto and internal wirings 19, and a probe substrate 15 fixed to the main substrate 16 and provided with electrodes 17 mounted with the probes 1. The tester 33 and the probe card 14 are separated from each other in a state shown in FIG. 5, but the tester 33 lowers so that the external terminals 18 contact with the pogo pins 34 at a measurement time. The leading end portion 5 of the probe 1 contacts with the electrode 35 of an object to be tested to carry out measurement.

In the probe card 14, electrically-conductive joining agents are provided on different two portions regarding the mounting portions 3 of adjacent probes 1 to join the probes 1 to the electrode 17 in order to arrange probes 1 at a narrow pitch. Thereby, plan arrangement of the probes 1 becomes such a state as shown in FIG. 6, where the electrically-conductive joining agents on the adjacent probes 1 are arranged in a staggered state so that the electrically-conductive joining agents on the adjacent probes 1 are prevented from contacting with each other.

By providing the electrically-conductive joining agents at different two portions regarding the adjacent probes 1 to join the probes to the electrode 17 in this manner, it becomes possible to arrange probes at a narrower pitch, for example, it becomes possible to arrange probes with a thickness of 40 μm at a pitch of 60 μm. Incidentally, in the embodiment, the case where all the intermediate layers 8 are protruded beyond the outer layers 9 is handled, but it goes without saying that a similar effect can be obtained even in such a case that the intermediate layers 8 are not protruded beyond the outer layers 9.

Next, a method for mounting the probe 1 on the probe card 14 according to the present invention is described. First of all, the probe hand mechanism 2 used when probe mounting is carried out is described. The probe hand mechanism 2 incorporates a heater (not shown) therein, and a hole for probe suction 11 which sucks the handling plate 6 of the probe 1 and probe positioning pins 12 used when the probe 1 is sucked are provided on a side face of the probe hand mechanism 2. Further, it is possible to incorporate a temperature sensor for managing a heating temperature of the probe 1 in the probe hand mechanism 2.

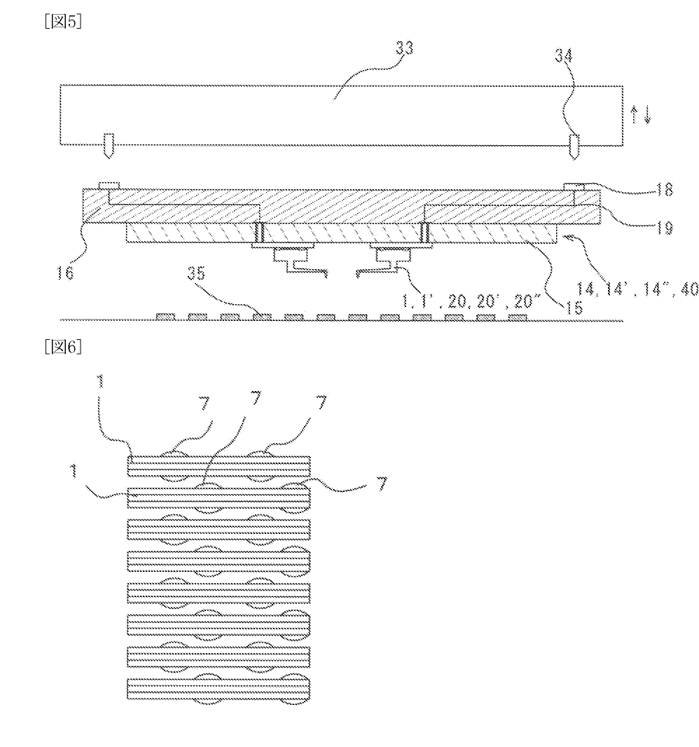

The probe 1 is mounted on the probe card 14 using the probe hand mechanism 2. First, as shown in FIG. 4, the probe 1 is held by the probe hand mechanism 2. At this time, positioning of the probe 1 is carried out in the probe hand mechanism 2 by the probe positioning pins 12, the handling plate 6 of the probe 1 is sucked by the hole 11 for suction, and the probe 1 is held by the probe hand mechanism 2.

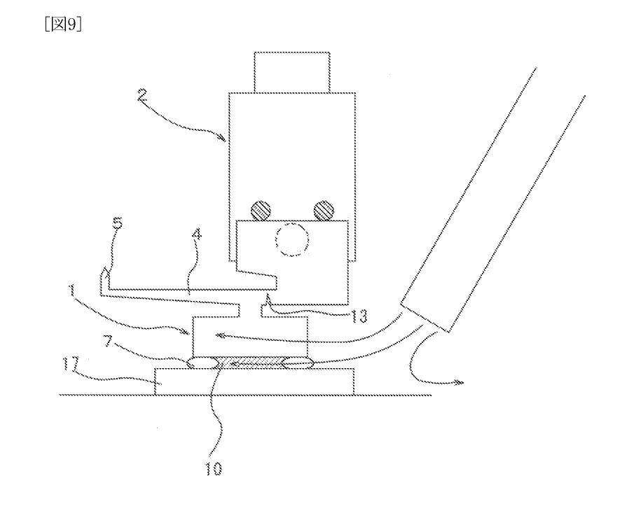

Next, the probe hand mechanism 2 moves to move the probe 1 above the electrode 17 provided on the probe substrate 15 of the probe card 14, as shown in FIG. 7, and to perform positioning. Then, the whole probe card 14 is pre-heated and heat is applied to the handling plate 6 of the probe 1 by the heater incorporated in the probe hand mechanism 2 to heat the probe 1, thereby melting the electrically-conductive joining agents provided at the two positions on the mounting portion 3 of the probe 1, and thereafter the probe 1 is pressed on the electrode 17, as shown in FIG. 8.

Next, heating conditions of the probe 1 are described. When lead-free solder is used as the electrically-conductive joining agent, it is necessary to heat the probe 1 to maintain the same in a range from 280° C. to 350° C. Further, since the heating temperature of the probe 1 must be a temperature at the mounting portion 3 of the probe 1, it is necessary to heat the handling plate 6 of the probe 1 heated by the incorporated heater of the probe hand mechanism 2 to a temperature equal to or higher than the above temperature (280° C. to 350° C.). As one example, when the handling plate 6 is heated at a temperature of about 500° C. for about 3 seconds, the temperature of the mounting portion 3 of the probe 1 rises up to a temperature near 300° C., it falls in a range of the heating temperature (280° C. to 350° C.) and it reaches a temperature suitable for solder melding.

The probe 1 is heated under such temperature conditions as described above to melt the electrically-conductive joining agents provided on the mounting portion 3. Then, the probe 1 is pressed on the electrode 17 of the probe card pre-heated and just after the electrically-conductive joining agents 17 have fitted in the electrode 17, heating to the probe 1 is terminated. By carrying out proper temperature control at the mounting time in this manner, it becomes possible to reduce influence to surrounding probes as much as possible.

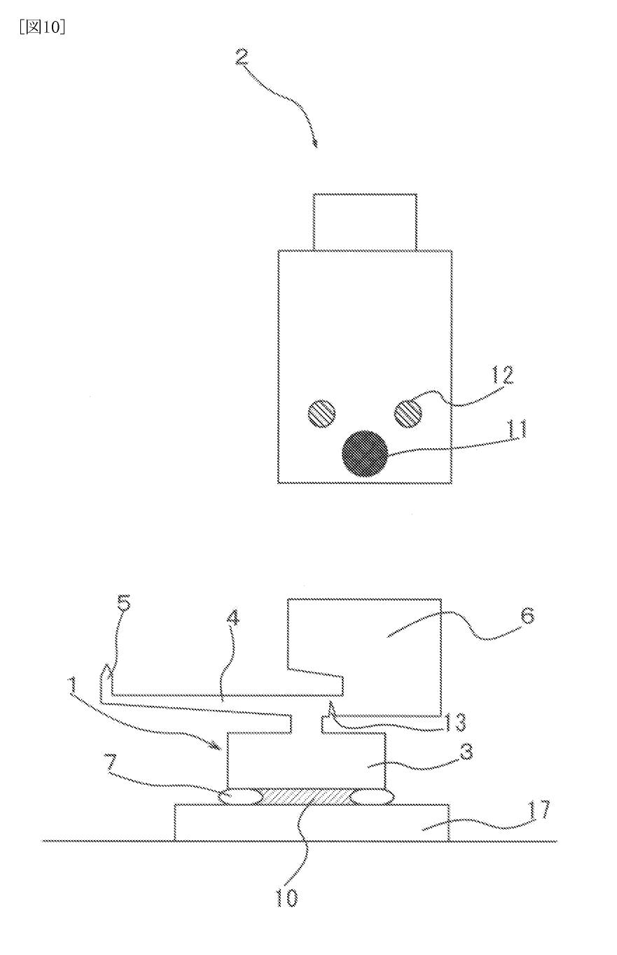

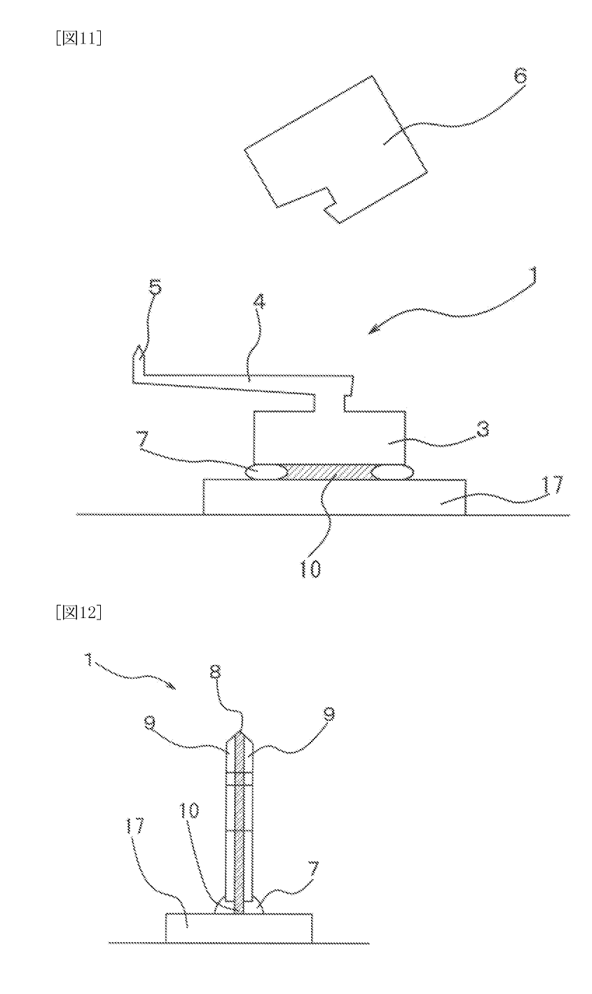

After heating to the probe 1 is terminated in this manner, as shown in FIG. 9, a re-mounting portion is locally cooled by air blow or the like. Thereby, it becomes possible to suppress thermal influence to surrounding probes further effectively. After the local cooling is terminated, as shown in FIG. 10, holding of the probe 1 performed by the probe hand mechanism 2 is released, and the handling plate 6 which has been become unnecessary is finally removed from the probe 1, as shown in FIG. 11. When the handling plate 6 is removed in this manner, a broken mark is left on the arm portion 4 of the probe 1. When the handling plate 6 has been provided on the mounting portion 3, the broken mark is left on the mounting portion 3. Owing to that the recessed portion 13 has been provided, the handling plate 6 can be easily removed from a main body of the probe 1. Joining of the probe 1 to the electrode 17 is completed in this manner.

At the joining time of the probe 1, as shown in FIG. 12, the electrically-conductive joining agent 7 is filled in step portions formed between the protruded portion 10 of the intermediate portion 8 and respective lower ends of the outer layers 9, so that remaining portions of the filled electrically-conductive joining agent 7 spread on both sides of the probe 1. Almost of the electrically-conductive joining agent conventionally spreads on both the sides of the probe 1, but since portions of the electrically-conductive joining agent 7 are filled in the step portions formed between the protruded portion 10 and the respective lower ends of the outer layers 9 in the probe 1 of the present invention, as described above, the amount of the electrically-conductive joining agent 7 spreading on both the sides of the probe 1 becomes small, and a spreading width also becomes small, so that an interval between adjacent probes can be made narrower than the conventional case.

Next, a probe 20 of a second embodiment is described in detail with reference to the drawings. The probe 20 of the second embodiment is formed with two independent protruded portions 10′ instead of the protruded portion 10 of the probe 1 of the first embodiment.

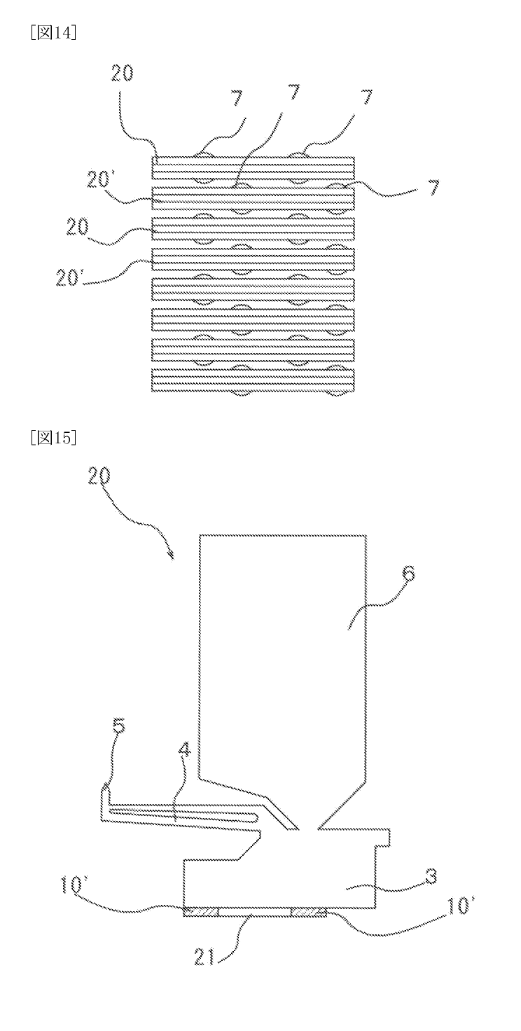

As shown in FIG. 13(a), the probe 20 of the second embodiment is composed of a mounting portion 3, an arm portion 4 extending from the mounting portion 3 and having a spring property, a leading end portion 5 provided at a leading end of the arm portion 4 and contacting with an electrode of an object to be tested, and a handling plate 6 extending from the mounting portion 3, and it has a three-layered structure where an intermediate layer 8′ is sandwiched between outer layers 9.

The intermediate layer 8′ and the outer layers 9 are each formed in a shape of the above-described mounting portion 3, arm portion 4, leading end portion 5, and handling plate 6, but a lower end (a portion contacts with an electrode of a probe card at a joining time to the probe card) of the mounting portion 3 of the intermediate layer 8 (8′) is provided with protruded portions 10′ at two portions protruded beyond the outer layers 9. Electrically-conductive joining agent 7 is provided on the protruded portions 10′ at two portions so that the probe 20 is mounted on a probe card 14′. Regarding a mounting method, it is carried out according to the same procedure as described in the first embodiment.

In this embodiment, since the protruded portions 10′ are provided at two portions, and a space occurs between the two protruded portions 10′, when the probe 20 is mounted, the heated electrically-conductive joining agent 7 flows out not only on the both sides of the probe 20 but also between two protruded portions 10′, so that the amount of the electrically-conductive joining agent 7 flowing out on the both sides of the probe 20 is further reduced, whereby it becomes possible to further reduce an interval between adjacent probes 20.

The probe card 14′ mounted with the probe cards 20 of the second embodiment is described. In the probe card 14′, two kinds of probes 20 and 20′ where the protruded portion 10′ have been provided at different two portions are used in order to arrange probes 20 at a narrow pitch. The probe card 14′ of the second embodiment includes a main substrate 16 having external terminals 18 connected to a tester and internal wirings 19 and a probe substrate 15 fixed to the main substrate 16 and mounted with an electrode 17 mounted with the probes 1 like the probe card 14 of the first embodiment.

As the probes mounted on the probe card 14′, as shown in FIGS. 13(a) and 13(b), the probes 20 and 20′ where the protruded portions 10′ have been provided at different two portions are prepared. The two kinds of probes 20 and 20′ are alternately mounted on the probe card 14′. Thereby, a plan arrangement of two kinds of probes 20 and 20′ becomes a state shown in FIG. 14, where the electrically-conductive joining agents 7 on adjacent probes 20 and 20′ are arranged in a staggered state, and a range where the electrically-conductive joining agents 7 of the adjacent probes 20 and 20′ contact with each other is reduced.

By arranging two kinds of probes 20 and 20′ different in positions of the protruded portions 10′ alternately in this manner, it is made possible to arrange the probes 20 and 20′ at a narrower pitch.

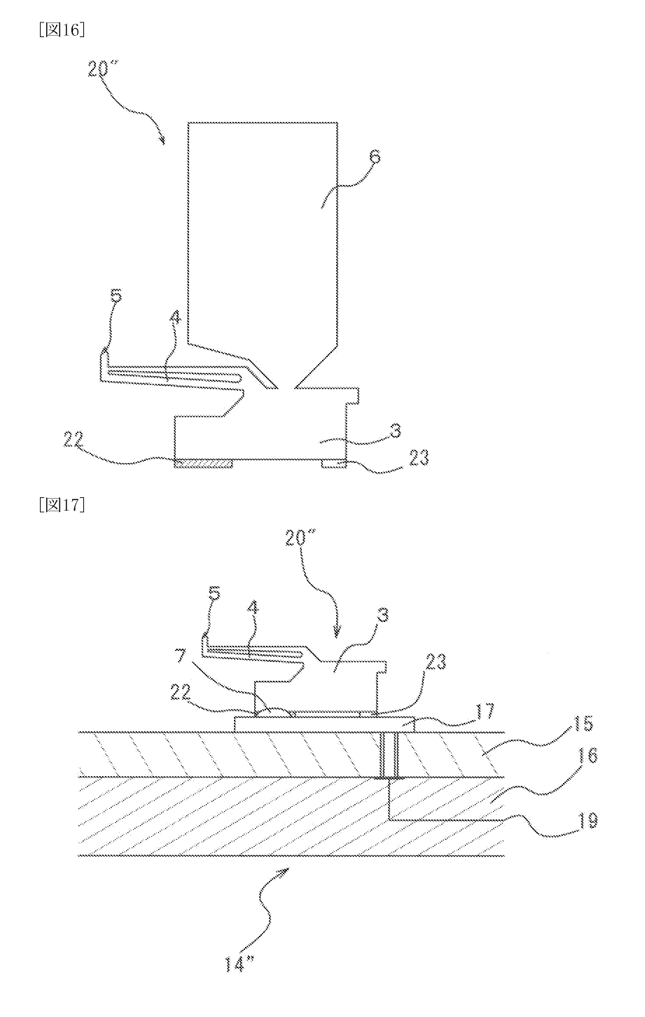

When two protruded portions 10′ are provided, since a contact range between the electrode 17′ of the probe card 14′ and the mounting portions of the probes 20 and 20′ is reduced, which results in a problem of strength shortage to a load applied at a joining time, a beam 21 is provided between two protruded portions 10′ in such a case, as shown in FIG. 15. The beam 21 can be provided in either of two outer layers 9 and the intermediate layer 8′ of three layers constituting the probe 20. By providing such a beam 21, strength shortage at the mounting time can be resolved.

Next, a probe 20″ of a third embodiment is described. FIG. 16 shows a side diagram of the probe 20″ of the third embodiment. The probe 20″ of the third embodiment is provided with two protruded portions 22 and 23 like the probe 20 of the second embodiment, but one protruded portion 22 is utilized as a joining portion 22 used for joining with a probe card, while another protruded portion 23 is utilized as a supporting portion 23 used as a mere support which is not utilized for joining with the probe card. The other structure of the probe 20″ is the same as the structure of the probe 20 of the second embodiment.

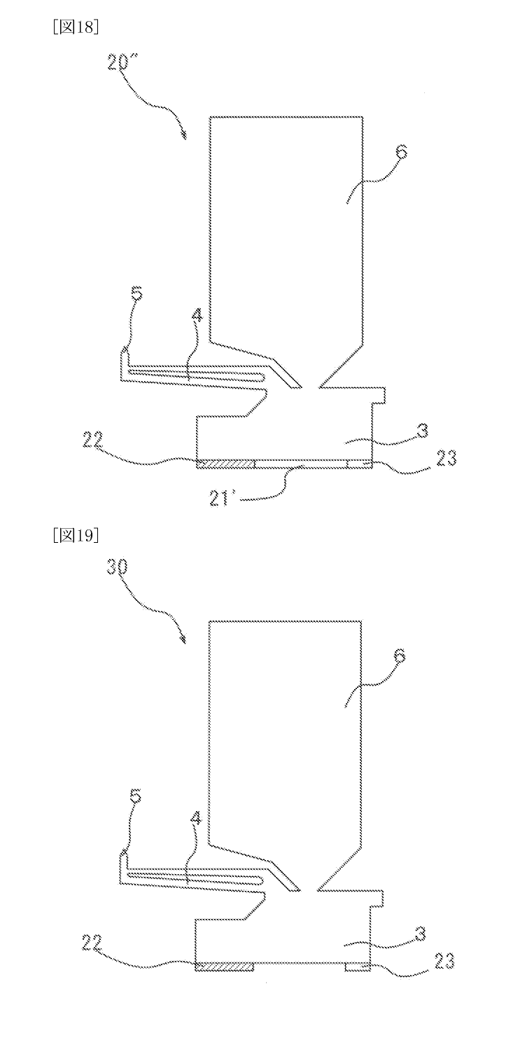

Accordingly, when the probe 20″ of this embodiment is mounted to the probe card 14″, as shown in FIG. 17, the electrically-conductive joining agent 7 is provided on only the joining portion 22 so that the probe 20″″ is joined to the probe card 14″. By fixing one joining portion 22, the probe 20″ can be mounted on the probe card 14″, but when the joining portion is only one joining portion 22, mounting becomes unstable, which results in deterioration of accuracy, so that stability at the mounting time is enhanced by providing the supporting portion 23.

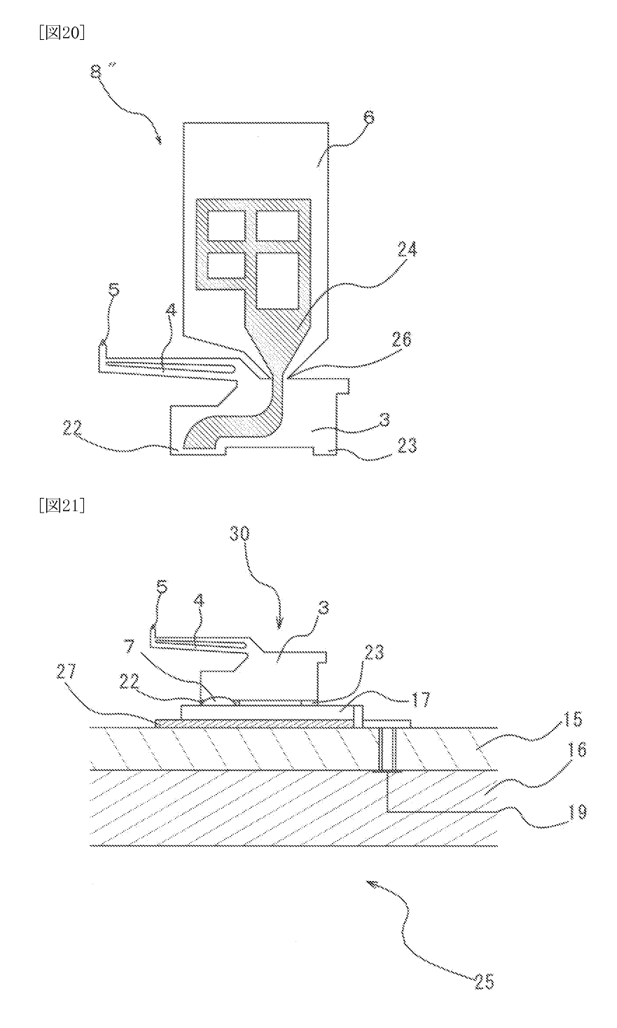

Further, since there is a problem about strength shortage to load applied at the mounting time like the probe 20 of the second embodiment, a beam 21′ is provided between the joining portion 22 and the supporting portion 23 in such a case, as shown in FIG. 18. The beam 21′ can be provided in either of two outer layers 9 and the intermediate layer 8′ of three layers constituting the probe 20″. By providing such a beam 21′, strength shortage at the mounting time can be resolved.

Next, a probe 30 of a fourth embodiment is described. The probe 30 of this embodiment has a heat conductivity enhanced by providing a copper line 24 in the intermediate layer 8′ of the probe 20″ of the third embodiment.

As shown in FIG. 19, the probe 30 of the fourth embodiment is composed of a mounting portion 3, an arm portion 4 extending from the mounting portion 3 and having a spring property, a leading end portion 5 provided at a leading end of the arm portion 4 and contacting with an electrode 17 of an object to be tested, and a handling plate 6 extending from the mounting portion 3, and it has a three-layered structure where an intermediate layer 8″ is sandwiched between outer layers 9.

Further, two protruded portions 22 and 23 are formed on the intermediate layer 8″ like the third embodiment, and the protruded portion 22 is utilized as a joining portion 22 used for joining with a probe card 25 while the protruded portion 23 is utilized as a supporting portion 23 used as a mere support which is not used for joining with the probe card 25. The electrically-conductive joining agent 7 is provided on the joining portion 22, thereby joining the probe 30 to an electrode 17 of the probe card 25 and mounting the same.

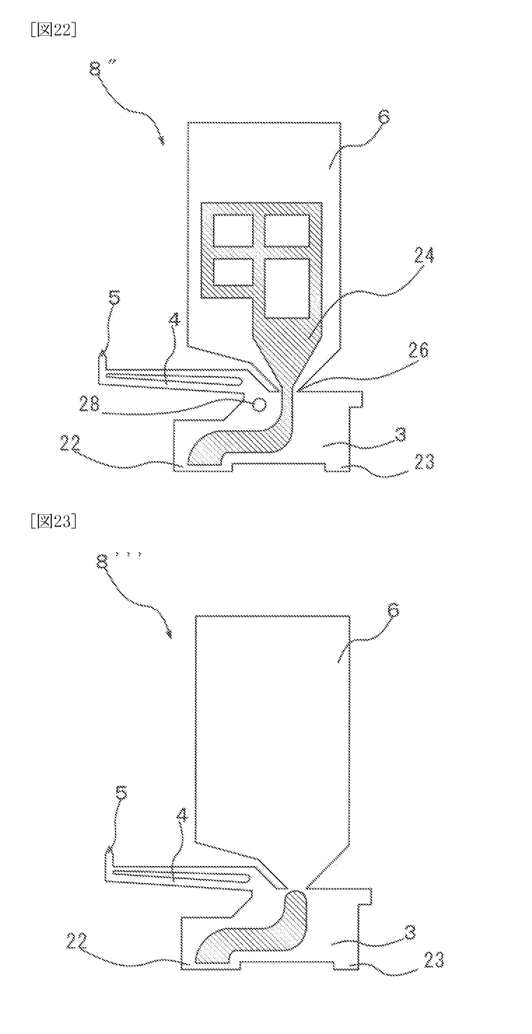

Further, in the probe 30 of this embodiment, the copper line 24 extending from the hand plate 6 to the joining portion 22 of the mounting portion 3, such as shown in FIG. 20, is provided on the intermediate layer 8″. At this time, blanks are provided in the copper line 24 on the portion of the handling plate 6.

A mounting method of the probe 30 to the probe card 25 according to this embodiment is the same method as the mounting method of the probe 20″ of the third embodiment, where the electrically-conductive joining agent 7 is provided on the joining portion 22, and joining to the electrode 17 of the probe card 25 is carried out. At this time, since heat applied to the handling plate 6 is transferred to the joining portion 22 through the copper line 24, the heat is transferred more efficiently as compared with the probes of the other embodiments which are not provided with the copper line 24, and solderability of the electrically-conductive joining agent 7 is improved, so that the probe 30 can be mounted without heating the handling plate 6 beyond necessity.

As described above, the reason why the blanks are provided in the copper line 24 on the portion of the handling plate 6 is because the probe 30 is prevented from deforming due to that the copper line 24 is surrounded by a portion of the intermediate layer 8″ which is other than the copper line 24 and the outer layers 9, the portion and the outer layers 9 being formed of a material other than copper which is different in expansion coefficient from the copper, and an excess copper line 24 is omitted by providing the blanks, so that deformation is reduced as much as possible. Further, by changing the size of a neck portion 26 through which the handling plate 6 and the mounting portion 3 are connected to each other, a heat supply amount to the joining portion 22 can also be adjusted.

Such a copper line 24 can be provided on the probes of the above-described first and second embodiments, and such a structure is adopted in the case that a copper line is branched at the mounting portion 3 to transfer heat to two portions.

Subsequently, the probe card 25 mounted with the probes 30 is described. The probe 20 is mounted on the electrode 17 of the probe card 25, but probes are joined by providing the electrode 17 directly on the probe substrate 15 in the probe cards described above.

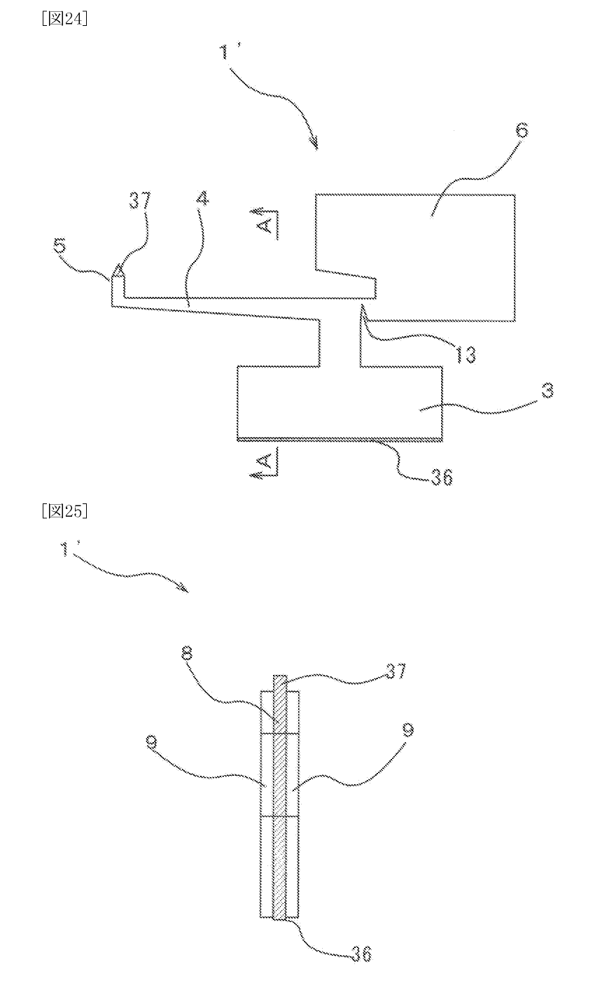

In this embodiment, however, as shown in FIG. 21, when the electrode 17 is provided on the probe substrate 15, such a structure is adopted that a treatment of glaze which is glass coat glaze is performed on a surface of the probe substrate 15 in advance, and the electrode 17 is provided on the formed glaze 27. This is for solving such a problem that heat applied when the probe 30 is mounted is transferred to the probe substrate 15 through the electrode 17 so that sufficient heat quantity cannot be secured for the joining portion.

For example, in such a case that a probe substrate 15 made of a ceramic substrate is used, when the probe 30 is joined to the electrode 17 provided directly on the probe substrate 15, heat applied to the electrically-conductive joining agent 7 escapes from the electrode 17 to the ceramic substrate due to the fact that the heat conductivity of the ceramic substrate is high, so that there is a possibility that heat quantity required for joining cannot be obtained. By providing the glaze 27 whose heat conductivity is low between the probe substrate 15 and the electrode 17 like the probe 30 of this embodiment, escape of heat can be suppressed.

Subsequently, a method of the glaze treatment is described. The glaze 27 is applied to a surface of the probe substrate 15 made of a ceramic substrate with a high heat conductivity or the like. An application range of the glaze 27 may be minimally a range covering a bottom region of the electrode 17, but the glaze 27 may be applied to the whole area of the probe substrate 15. After the glaze application, sinter is carried out in a temperature range from 600 to 700° C. Thereafter, the electrode 17 is formed. A mounting method of the probe 40 carried out thereafter may be the same method as described above.

Carrying out the glaze treatment in this manner lowers the heat conductivity simply while also smoothing a surface of the probe substrate, and it also achieves such an effect that pattern recognition of a prober or the like is made easy.

Further, as shown in FIG. 22, by providing an opening 28 in the vicinity of connection of the arm portion 4 to the mounting portion 3 of the intermediate layer 8″ of the probe 30, adverse influence due to transfer of heat to the arm portion 4 at a joining time of the probe 30 can be prevented.

Next, a probe 30′ of a fifth embodiment is described. The probe 30′ of this embodiment uses a heat pipe structure instead of the copper line 24 of the probe 30 of the fourth embodiment, and the other structure thereof is the same as the fourth embodiment.

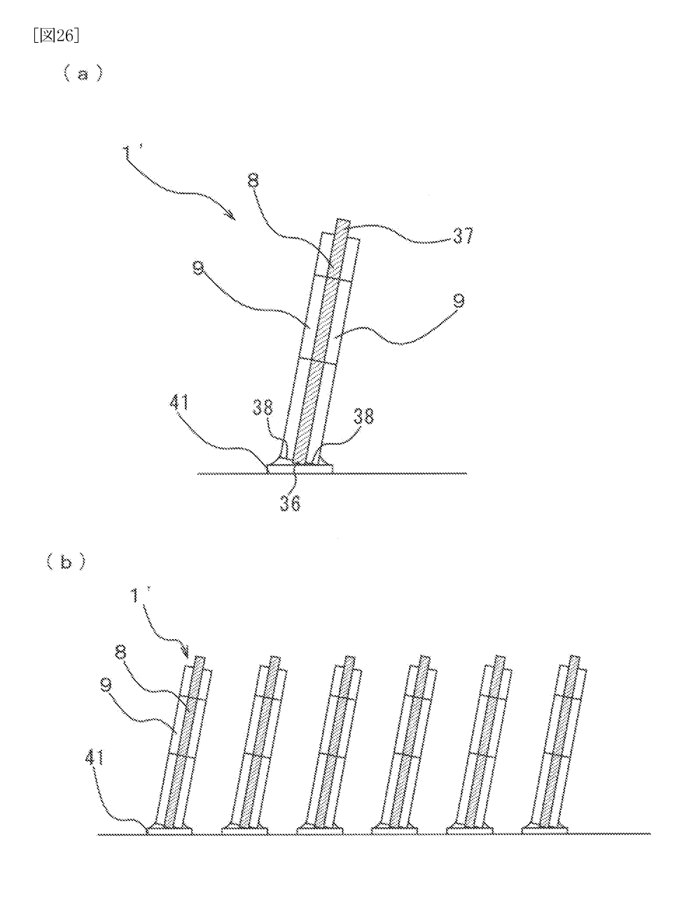

The heat pipe structure is configured as a super heat transfer structure where a range shown by a slash mark in FIG. 23 has a hollow structure and a wick structure and a working fluid which is solid in the normal temperature are provided in the hollow structure. The heat conductivity from the handling plate 6 to the joining portion 22 is improved by such a heat pipe structure like the case where the copper line 24 has been provided, so that solderability of the electrically-conductive joining agent 7 is improved.

Thus, the probe of the present invention resolves the problem occurring due to heat at replacement and mounting times of the conventional probe, and a probe and a probe card which can be handled easily and allow arrangement at a narrow pitch can be realized.

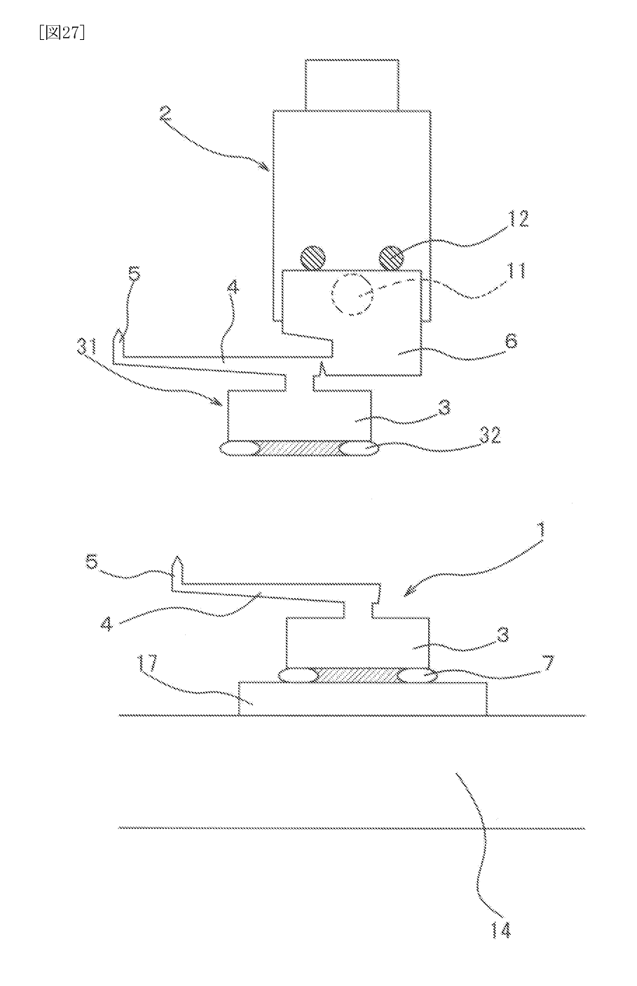

Next, a probe 1′ of a sixth embodiment is described. The probe 1′ of this embodiment has a structure obtained by reducing a protrusion amount of the protruded portion 10 of the probe 1 of the first embodiment and also protruding the intermediate layer of the leading end portion 5. As shown in FIG. 25, the probe 1′ of this embodiment has a three-layered structure where the intermediate layer 8 has been sandwiched between the outer layer 9, and, as shown in FIGS. 24 and 25, a lower end of the mounting portion 3 of the intermediate layer 8 forms a protruded portion 36 slightly protruded beyond the outer layers 9, while a leading end of the leading end portion 5 of the intermediate layer 8 forms a protruded portion 37 protruded beyond the outer layers 9. The protruded portion 37 of the leading end portion 5 contacts with an electrode 35 of an object to be tested.

When the probe 1′ of this embodiment is mounted on a probe card 40, instead of causing only the protruded portion 36 to contact with the electrode 41 of the probe card 40 to carry out joining, the protruded portion 36 and a bottom face 38 of either one of two outer layers 9 are caused to contact with the electrode 38 to carry out joining unlike the probes in the other embodiments.

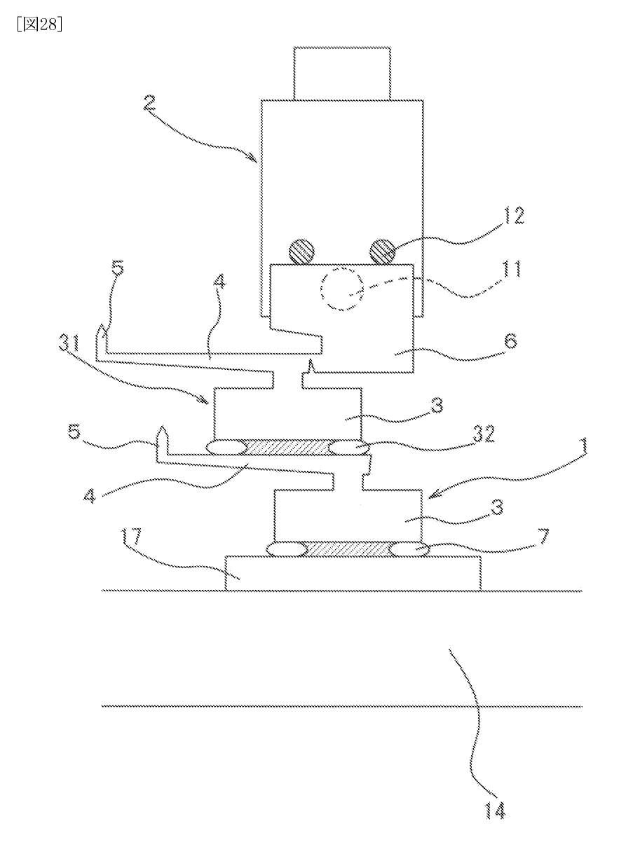

When the probe 1′ is joined to the electrode 41 in such a state, as shown in FIG. 26(a), joining of the probe 1′ is achieved in a state that the probe 1′ has been inclined to the side of one of the outer layers 9 (in a rightward inclined state in this embodiment). When the probes 1′ are mounted on the probe card 41 in this manner, if joining is performed such that adjacent probes 1′ are inclined in the same direction (rightward in FIG. 26), as shown in FIG. 26(b), inclination directions and inclination amounts of all adjacent probes 1′ coincide with each other, respectively, so that distances from the probe substrate 15 to the leading end portions 5 of the probes 1′ become constant, it becomes possible to uniform the positions of the leading end portions 5, the position accuracy of the probes 1′ become high, and adjacent probes 1 are prevented from short-circuiting due to contacting with each other resulting from inclination. However, inclination directions of all the probes 1′ to be mounted on the probe card 41 are not caused to coincide with one another, but inclination directions of the probes 1′ can be changed, for example, for each row thereof or each block thereof in conformity with arrangement of the probes 1′.

Next, a method for removing a mounted probe 1 on the probe card 14 using the probes described above is described. Here, description is made using the probe 1 and the probe card 14 described in the first embodiment.

When the probe card 14 is used repeatedly, there is a case where the probe 1 is broken. At this time, it is necessary to remove the broken probe 1 to mount a new probe 1. As a method for mounting a new probe 1, the mounting methods of a probe described above can be used, but it is necessary to remove the broken probe 1 before a new probe 1 is mounted.

Therefore, when the broken probe 1 is removed, it can be removed by using an unmounted probe 31 more easily as compared with the conventional case. The unmounted probe 31 is held by the probe hand mechanism 2. At this time, positioning of the unmounted probe 31 is performed in the probe hand mechanism 2 by the probe positioning pins 12, and the handling plate 6 of the unmounted probe 31 is sucked by the suction hole 11, so that the unmounted probe 31 is held by the probe hand mechanism 2.

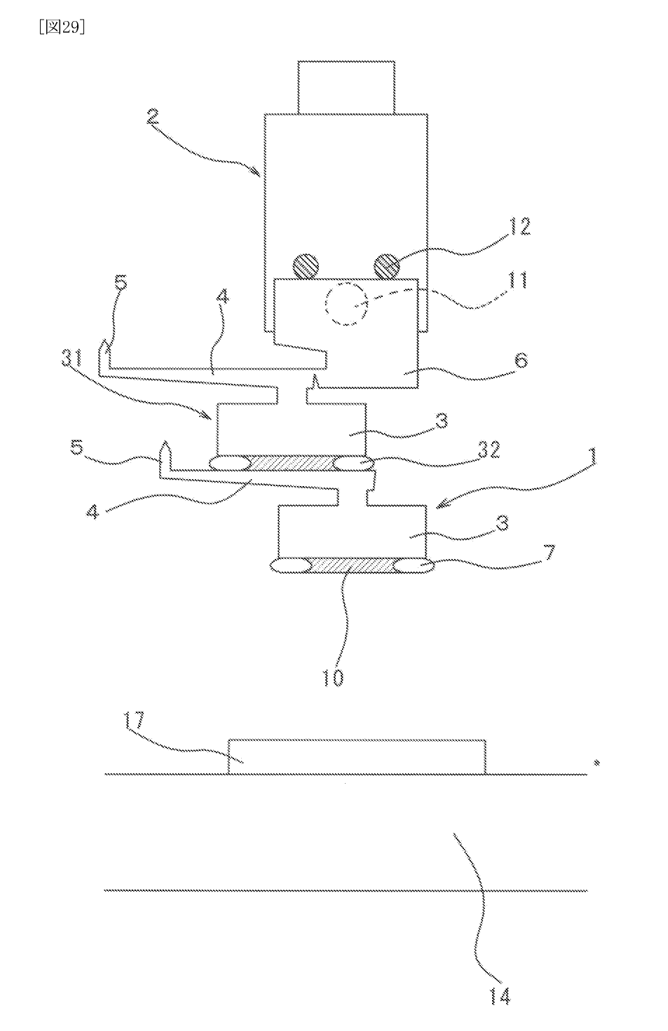

Next, the probe hand mechanism 2 moves to move the unmounted probe 1 above the probe 1 required for replacement and position the unmounted probe 31, as shown in FIG. 27. Then, as shown in FIG. 28, the probe hand mechanism 2 applies heat to the handling plate 6 of the unmounted probe 31 by the incorporated heater in such a state that the mounting portion 3 of the unmounted probe 31 has been pressed on the arm portion 5 of the mounted probe 1 required for replacement to heat the unmounted probe 31, thereby melting electrically-conductive joining agents 32 provided on two portions of the mounting portion 3 of the unmounted probe 31.

Here, as the electrically-conductive joining agent 7 of the mounted probe 1, Sn—Pb solder is used, while Sn—Ag solder higher in melting point than the Sn—Pb solder is used as the electrically-conductive joining agent 32 provided on the unmounted probe 31. Thereby, when the unmounted probe 31 is heated, heat thereof is transferred to the mounted probe 1 so that the electrically-conductive joining agent 7 joining the mounted probe 1 is also melted.

The heating temperature of the handling plate 6 is caused to lower to join the unmounted probe 31 to the mounted probe 1. At this time, when the heating temperature to be lowered is caused to lower to a temperature between the melting point of the electrically-conductive joining agent 7 and the melting point of the electrically-conductive joining agents 32, the unmounted probe 31 and the mounted probe 1 are joined to each other by the electrically-conductive joining agent 32 and the electrically-conductive joining agent 7 is put in a melted state.

In such a state, when force is applied to the unmounted probe 31 and twisting is performed by the probe hand mechanism 2, the mounted probe 1 is also twisted, so that the mounted probe 1 is removed from the probe card 14, as shown in FIG. 29. At this time, as described above, the mounted probe 1 can be removed easily if the electrically-conductive joining agent 7 is in a melted state.

Further, in a case that the electrically-conductive joining agent 32 and the electrically-conductive joining agent 7 have the same melting point, when the heating temperature by the probe hand mechanism 2 is caused to lower, it is possible to facilitate removal of the mounted probe 1 by stopping heating and maintaining heating of the probe card 14 in a state that the unmounted probe 31 and the mounted probe 1 have been completely joined to each other.

After the mounted probe 1 has been removed in this manner, when a new probe 1 is mounted on the probe card 14 by the method described above, replacement of the probe 1 is completed.

In this way, by the removing method of a mounted probe on a probe card using the probe of the present invention, the mounted probe can be removed easily, while influence to another probe is reduced as compared with the conventional case.

### REFERENCE SIGNS LIST

1, 1′ probe
2 probe hand mechanism
3 mounting portion
4 arm portion
5 leading end portion
6 handling plate
7 electrically-conductive joining agent
8, 8′, 8″, 8′″ intermediate layer
9 outer layer
10, 10′ protruded portion
11 hole for probe suction
12 probe positioning pin
13 recessed portion
14, 14′, 14″ probe card
15 probe substrate
16 main substrate
17 electrode
18 external terminal
19 internal wiring
20, 20′, 20″ probe
21, 21′ beam
22 joining portion
23 supporting portion
24 copper line
25 probe card
26 neck portion
27 glaze
28 opening
30 probe
31 unmounted probe
32 electrically-conductive joining agent
33 tester
34 Pogo pin
35 electrode
36 protruded portion
37 protruded portion
38 bottom face
40 probe card
41 electrode

1. A probe, which is composed of a mounting portion mounted on an electrode of a probe card, an arm portion extending from the mounting portion, and a leading end portion which is provided at a leading end of the arm portion and which is configured to contact an electrode of an object to be tested,
comprising a handling plate configured to be removed from said probe.

2. The probe according to claim 1, wherein:
said handling plate is configured to be held by a probe hand mechanism configured to heat said probe.

3. The probe according to claim 1
said handling plate has a suction face configured to be sucked by the probe hand mechanism.

4. The probe according to claim 1 wherein:
said handling plate has a recessed portion configured to provide a cutting edge.

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)
